(19) United States
(12) Patent Application Publication
(10) Pub. No.: US 2025/0098442 A1
(43) Pub. Date: Mar. 20, 2025

(54) DISPLAY PANEL AND DISPLAY APPARATUS

(71) Applicants: Hefei Visionox Technology Co., Ltd., Hefei (CN); KunShan Go-Visionox Opto Electronics Co., Ltd, Kunshan (CN)

(72) Inventors: Yuan YAO, Hefei (CN); Bo RAO, Hefei (CN); Mingchen LI, Hefei (CN); Lipeng GAO, Hefei (CN)

(73) Assignees: Hefei Visionox Technology Co., Ltd., Hefei (CN); KunShan Go-Visionox Opto Electronics Co., Ltd, Kunshan (CN)

(21) Appl. No.: 18/650,670

(22) Filed: Apr. 30, 2024

(30) Foreign Application Priority Data
Sep. 20, 2023 (CN) 202311221918.4

(51) Int. Cl. H10K 59/126; H10K 59/122; H10K 59/131; H10K 59/40

(52) U.S. Cl. CPC H10K 59/126; H10K 59/122; H10K 59/131; H10K 59/40

(57) ABSTRACT

A display panel and a display apparatus. The display panel includes a display area and a non-display area, and the display panel further includes: an array base plate; a light-emitting layer arranged on the array base plate and including a plurality of light-emitting units; an isolation structure located in the display area, the isolation structure being arranged on the array base plate and including a plurality of isolation openings, the light-emitting units being located within the isolation openings; a first shielding structure located in the non-display area and arranged in the same layer as at least a portion of the isolation structure; and a touch control component at least partially located at a side of the first shielding structure away from the array base plate.

### CROSS REFERENCE TO RELATED APPLICATION

The present application claims priority to Chinese Patent Application No. 202311221918.4 filed on Sep. 20, 2023, which is incorporated herein by reference in its entirety.

### TECHNICAL FIELD

The present application relates to the field of display technology, and particularly to a display panel and a display apparatus.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the performance of current OLED display products needs to be improved.

### SUMMARY

Embodiments of the present application provide a display panel and a display apparatus, aiming to reduce mutual interference between the touch control signals and other signals in the display panel.

Some embodiments of a first aspect of the present application provide a display panel with a display area and a non-display area, the display panel includes: an array base plate; a light-emitting layer arranged on the array base plate and including a plurality of light-emitting units; an isolation structure located in the display area, the isolation structure being arranged on the array base plate and including a plurality of isolation openings, the light-emitting units being located within the isolation openings; a first shielding structure located in the non-display area and arranged in the same layer as at least a portion of the isolation structure; and a touch control component at least partially located at a side of the first shielding structure away from the array base plate.

According to an implementation of the first aspect of the present application, each of at least a portion of the isolation structure and at least a portion of the first shielding structure includes an electrically conductive material.

According to any of the above implementation of the first aspect of the present application, the isolation structure and the first shielding structure are arranged in a same layer and each of the isolation structure and the first shielding structure includes a one-piece structure.

According to any of the above implementation of the first aspect of the present application, each of the isolation structure and the first shielding structure includes a first end portion facing the array base plate and a second end portion away from the array base plate, an orthographic projection of the first end portion of the isolation structure on the array base plate is located within an orthographic projection of the second end portion of the isolation structure on the array base plate, and an orthographic projection of the first end portion of the first shielding structure on the array base plate is located within an orthographic projection of the second end portion of the first shielding structure on the array base plate.

According to any of the above implementation of the first aspect of the present application, each of the first end portion of the isolation structure and the first end portion of the first shielding structure includes the electrically conductive material.

According to any of the above implementation of the first aspect of the present application, the isolation structure includes a first isolation portion and a second isolation portion arranged at a side of the first isolation portion away from the array base plate, an orthographic projection of the first isolation portion on the array base plate is located within an orthographic projection of the second isolation portion on the array base plate, the first shielding structure includes a first shielding portion and a second shielding portion arranged at a side of the first shielding portion away from the array base plate, and an orthographic projection of the first shielding portion on the array base plate is located within an orthographic projection of the second shielding portion on the array base plate.

According to any of the above implementation of the first aspect of the present application, the first shielding portion and the first isolation portion are arranged in a same layer and formed with a same material, and/or the second shielding portion and the second isolation portion are arranged in a same layer and formed with a same material.

According to any of the above implementation of the first aspect of the present application, the first shielding portion and the first isolation portion include the electrically conductive material.

According to any of the above implementation of the first aspect of the present application, the first shielding structure is connected to a direct current voltage signal end of the display panel.

According to any of the above implementation of the first aspect of the present application, a signal line of the direct current voltage signal end includes at least one of a touch control ground signal line, an initialization signal line, a negative supply voltage signal line, or a positive supply voltage signal line.

According to any of the above implementation of the first aspect of the present application, the first shielding structure includes a plurality of first shielding openings.

According to any of the above implementation of the first aspect of the present application, a plurality of the first shielding openings are arranged at intervals in a first direction and/or a second direction.

According to any of the above implementation of the first aspect of the present application, an orthographic projection of a portion of the touch control component located in the non-display area on the array base plate is located within an orthographic projection of the first shielding structure on the array base plate.

According to any of the above implementation of the first aspect of the present application, the array base plate further includes a drive circuit, and an orthographic projection of the drive circuit located in the non-display area on the array base plate is located within the orthographic projection of the first shielding structure on the array base plate.

According to any of the above implementation of the first aspect of the present application, the display panel further includes a second shielding structure located at a side of the first shielding structure facing the array base plate, an orthographic projection of at least a portion of the second shielding structure in a thickness direction of the display panel covers the first shielding openings.

According to any of the above implementation of the first aspect of the present application, the display panel further includes a pixel defining layer arranged at a side of the array base plate, the pixel defining layer includes one or more pixel defining portions and a plurality of pixel openings defined by the pixel defining portions.

According to any of the above implementation of the first aspect of the present application, the pixel defining portions further define a plurality of third shielding openings located in the non-display area, an orthographic projection of at least a portion of the second shielding structure in the thickness direction of the display panel covers the third shielding openings.

According to any of the above implementation of the first aspect of the present application, the second shielding structure includes an electrically conductive material.

According to any of the above implementation of the first aspect of the present application, the second shielding structure is connected to a direct current voltage signal end of the display panel.

According to any of the above implementation of the first aspect of the present application, a signal line of the direct current voltage signal end includes at least one of an initialization signal line, a negative supply voltage signal line, or a positive supply voltage signal line.

According to any of the above implementation of the first aspect of the present application, the second shielding structure includes a plurality of second shielding openings, an orthographic projection of at least a portion of the first shielding structure in the thickness direction of the display panel covers the second shielding openings.

According to any of the above implementation of the first aspect of the present application, a plurality of the second shielding openings are arranged at intervals in the first direction and/or the second direction.

According to any of the above implementation of the first aspect of the present application, the orthographic projection of the first shielding structure on the array base plate is located within an orthographic projection of the second shielding structure on the array base plate, or the orthographic projection of the first shielding structure on the array base plate overlaps the orthographic projection of the second shielding structure on the array base plate.

According to any of the above implementation of the first aspect of the present application, an orthographic projection of an inner wall of the second shielding opening on the array base plate and an orthographic projection of an inner wall of the first shielding opening on the array base plate is separated by a preset spacing greater than or equal to 20 micrometers.

According to any of the above implementation of the first aspect of the present application, the preset spacing is greater than or equal to 25 micrometers and less than or equal to 35 micrometers.

According to any of the above implementation of the first aspect of the present application, the second shielding structure is arranged between the first shielding structure and the drive circuit of the array base plate, an orthographic projection of at least a portion of the drive circuit on the array base plate is located within an orthographic projection of the second shielding structure on the array base plate.

According to any of the above implementation of the first aspect of the present application, the display panel further includes a first electrode layer arranged at a side of the array base plate, and the first electrode layer includes a plurality of first electrodes arranged within the isolation openings.

According to any of the above implementation of the first aspect of the present application, the second shielding structure is arranged in the same layer as the first electrode.

According to any of the above implementation of the first aspect of the present application, at least a portion of the second shielding structure is arranged in the same layer as the first electrode and is formed with the same material as the first electrode, and/or at least a portion of the second shielding structure is arranged in the same layer as at least a portion of a power signal line of the display panel, and/or at least a portion of the second shielding structure is arranged in the same layer as at least a portion of a data signal line of the display panel.

According to any of the above implementation of the first aspect of the present application, at least a portion of the second shielding structure is arranged in the same layer as at least a portion of a power signal line of the display panel, and/or at least a portion of the second shielding structure is arranged in the same layer as at least a portion of a data signal line of the display panel.

According to any of the above implementation of the first aspect of the present application, the display panel further includes a second electrode layer arranged in the display area, and the second electrode layer includes a plurality of second electrodes arranged within the isolation openings, and the second electrode is located at a side of the light-emitting unit away from the array base plate.

Some embodiments of a first aspect of the present application further provide a display panel with a display area and a non-display area, the display panel includes: an array base plate; a light-emitting layer arranged on the array base plate and including a plurality of light-emitting units; a shielding layer located in the non-display area and arranged at a side of the light-emitting layer facing the array base plate, the shielding layer including a first shielding layer and a second shielding layer located at a side of the first shielding layer away from the light-emitting layer; and a touch control component at least partially located at a side of the shielding layer away from the array base plate.

According to an implementation of the first aspect of the present application, the shielding layer is arranged between the touch control component and a driving circuit of the array base plate, an orthographic projection of at least a portion of the drive circuit on the array base plate is located within an orthographic projection of the shielding layer on the array base plate.

According to any of the above implementation of the first aspect of the present application, the display panel further includes a first electrode layer arranged at a side of the array base plate, and the first electrode layer includes a plurality of first electrodes arranged between the light-emitting units and the array base plate.

According to any of the above implementation of the first aspect of the present application, at least a portion of the shielding layer is arranged in the same layer as the first electrode, and/or at least a portion of the shielding layer is arranged in the same layer as at least a portion of a power signal line of the display panel, and/or at least a portion of the shielding layer is arranged in the same layer as at least a portion of a data signal line of the display panel.

According to any of the above implementation of the first aspect of the present application, the shielding layer includes one or more air holes.

According to any of the above implementation of the first aspect of the present application, each of the first shielding layer and the second shielding layer includes the air hole, in which an orthographic projection of at least a portion of the first shielding layer in a thickness direction of the display panel covers the air hole in the second shielding layer, and/or an orthographic projection of at least a portion of the second shielding layer in the thickness direction of the display panel covers the air hole in the first shielding layer.

Some embodiments of a second aspect of the present application provide a display apparatus including the display panel according to any of the above implementation.

The display panel according to the embodiments of the present application includes the display area and the non-display area, and the display panel further includes the array base plate, the light-emitting layer, the isolation structure, the first shielding structure, and the touch control component. The isolation structure is arranged on the array base plate in the display area and includes a plurality of isolation opening, and the light-emitting units in the light-emitting layer are arranged within the isolation openings, so that the isolation structure can be used to divide the sub-pixels of the display panel.

The first shielding structure is located in the non-display area, and at least a portion of the touch control component is arranged at a side of the first shielding structure away from the array base plate, so that the first shielding structure can better control the signal in the array base plate to be transmitted to the touch control component, which is beneficial to reducing mutual interference between the signal in the array base plate and the touch control signal in the touch control component, so as to improve the working reliability of the display panel. Moreover, the first shielding structure is arranged in the same layer as at least a portion of the isolation structure, so that the first shielding structure and the isolation structure can be manufactured in a same process step, and thus not only mutual interference between the touch control signals and other signals in the display panel can be reduced through the first shielding structure, but also the manufacturing process of the display panel can be simplified, so as to increase the manufacturing efficiency of the display panel.

### BRIEF DESCRIPTION OF THE DRAWINGS

In order to more clearly illustrate the technical solutions of the embodiments of the present application, the drawings to be used in the embodiments of the present application will be briefly introduced below. It is obvious that the drawings described below are merely some embodiments of the present application, and for those of ordinary skill in the art, other drawings can be obtained based on these drawings without inventive effort.

FIG. 1 shows a schematic structural diagram of a display panel according to an embodiment of the present application;

FIG. 2 shows a partial sectional view of a display panel according to an embodiment of the present application;

FIG. 3 shows a partial sectional view of a display panel according to another embodiment of the present application;

FIG. 4 shows a partial sectional view of a display panel according to yet another embodiment of the present application;

FIG. 5 shows a partial schematic structural diagram of a first shielding structure according to an embodiment of the present application;

FIG. 6 shows a partial sectional view of a display panel according to yet another embodiment of the present application;

FIG. 7 shows a partial sectional view of a display panel according to yet another embodiment of the present application;

FIG. 8 shows a partial schematic structural diagram of a first shielding structure and a second shielding structure according to an embodiment of the present application;

FIG. 9 shows a partial sectional view of a display panel according to yet another embodiment of the present application; and

FIG. 10 shows a partial sectional view of a display panel according to yet another embodiment of the present application.

### REFERENCE NUMERALS

10, display panel; 10a, first end portion; 10b, second end portion; 11, shielding layer; 11a, first shielding layer; 11b, second shielding layer; 11c, air hole;

100, array base plate; 110, substrate; 120, first insulating layer; 130, second insulating layer; 140, third insulating layer; 150, fourth insulating layer; 160, fifth insulating layer; 170, drive circuit; 171, transistor; 171a, gate; 171b, source; 171c, drain; 172, storage capacitor; 172a, first electrode plate; 172b, second electrode plate;

200, second shielding structure; 200a, second shielding opening;

300, first electrode layer; 310, first electrode;

400, pixel defining layer; 410, pixel defining portion; 410a, accommodating groove; 420, pixel opening;

500, isolation structure; 500a, isolation opening; 510, first isolation portion; 520, second isolation portion;

600, first shielding structure; 600a, first shielding opening; 610, first shielding portion; 620, second shielding portion;

700, light-emitting layer; 710, light-emitting unit;

800, second electrode layer; 810, second electrode;

900, touch control component;

AA, display area;

NA, non-display area;

X, thickness direction;

Y, first direction;

Z, second direction.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

It should be understood that when describing the structure of a component, if a layer/area is referred to as being “on” or “above” another layer/region, it may mean that the layer/area is directly on the other layer/region or that other layers/regions may be included between the layer/area and the other layer/area. Moreover, if the component is turned over, the layer/region will be “below” or “under” the other layer/region.

Planar display apparatus based on Organic Light Emitting Diode and Light Emitting Diode, etc., are widely used in cell phones, TVs, notebook computers, desktop computers and other consumer electronic products due to their high image quality, power saving, thin body and wide range of applications, and have become the mainstream of the display apparatus. However, the performance of current OLED display products needs to be improved.

In order to solve the above problems, the embodiments of the present application provide a display panel and a display apparatus, and various embodiments of the display panel and the display apparatus will be described below in connection with the accompanying drawings.

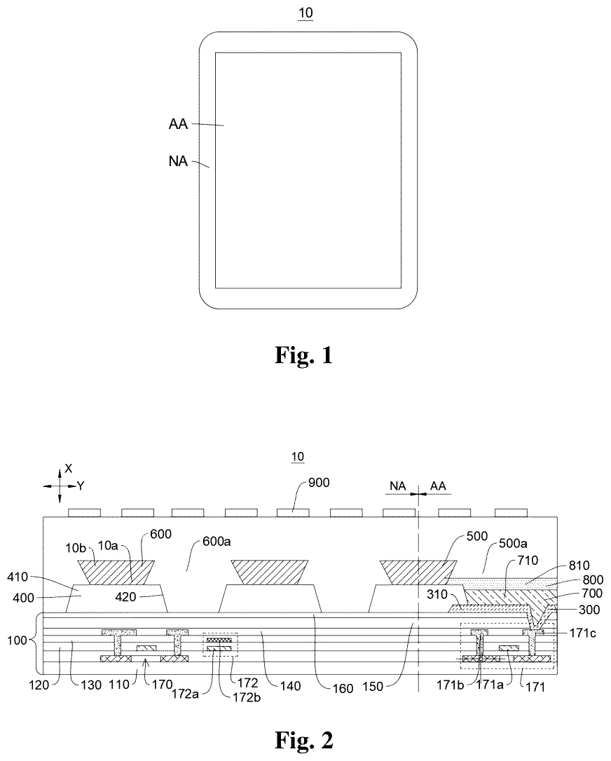

FIG. 1 shows a schematic structural diagram of a display panel 10 according to an embodiment of the present application, and FIG. 2 shows a partial sectional view of a display panel 10 according to an embodiment of the present application. In the figures, direction X is a thickness direction of the display panel 10, direction Y is a first direction, and direction Z is a second direction, in which the first direction Y, the second direction Z, and the thickness direction X are intersected with each other.

As shown in FIGS. 1 and 2, the embodiments of the present application provide a display panel 10, which may be an Organic Light Emitting Diode (OLED) display panel.

As shown in FIGS. 1 and 2, the embodiments of the first aspect the present application provide a display panel 10 with a display area AA and a non-display area NA, and the display panel 10 includes: an array base plate 100; a light-emitting layer 700 arranged on the array base plate 100 and including a plurality of light-emitting units 710; an isolation structure 500 located in the display area AA, the isolation structure 500 being arranged on the array base plate 100 and including a plurality of isolation openings 500a, the light-emitting units 710 being located within the isolation openings 500a; a first shielding structure 600 located in the non-display area NA and arranged in the same layer as at least a portion of the isolation structure 500; and a touch control component 900 at least partially located at a side of the first shielding structure 600 away from the array base plate 100.

The display panel 10 according to the embodiments of the present application includes the display area AA and the non-display area NA, and the display panel 10 further includes the array base plate 100, the light-emitting layer 700, the isolation structure 500, the first shielding structure 600, and the touch control component 900. The isolation structure 500 is arranged on the array base plate 100 in the display area AA and includes a plurality of isolation openings 500a, and the light-emitting units 710 in the light-emitting layer 700 are arranged within the isolation openings 500a, so that the isolation structure 500 can be used to divide the sub-pixels of the display panel 10.

The first shielding structure 600 is located in the non-display area NA, and at least a portion of the touch control component 900 is arranged at a side of the first shielding structure 600 away from the array base plate 100, so that the first shielding structure 600 can better control the signal in the array base plate 100 to be transmitted to the touch control component 900, which is beneficial to reducing mutual interference between the signal in the array base plate 100 and the touch control signal in the touch control component 900, so as to improve the working reliability of the display panel 10. Moreover, the first shielding structure 600 is arranged in the same layer as at least a portion of the isolation structure 500, so that the first shielding structure 600 and the isolation structure 500 can be manufactured in a same process step, and thus not only mutual interference between the touch control signals and other signals in the display panel 10 can be reduced through the first shielding structure 600, but also the manufacturing process of the display panel 10 can be simplified, so as to increase the manufacturing efficiency of the display panel 10.

The array base plate 100 may be set in various manners, and for example, the array base plate 100 may include a substrate 110 and one or more drive circuits 170 arranged on the substrate 110. Optionally, the array base plate includes a first insulating layer 120, a second insulating layer 130, and a third insulating layer 140 that are stacked. Exemplarily, the drive circuit 170 may include a transistor 171, a storage capacitor 172, and drive signal lines for connecting the individual devices, etc. The transistor 171 includes a semiconductor, a gate 171a, a source 171b, and a drain 171c. The storage capacitor 172 includes a first electrode plate 172a and a second electrode plate 172b. As an example, the gate 171a and the first electrode plate 172a may be located in the first insulating layer 120, the second electrode plate 172b may be located in the second insulating layer 130, and the source 171b and the drain 171c may be located in the third insulating layer 140.

The touch control component 900 may include a touch control electrode and some signal lines connected with the touch control electrode, and for example, a touch control ground signal line, a touch control drive signal line, a touch control receive signal line, and the like.

In some embodiments of the present application, the isolation structure 500 may be arranged in the display area AA of the display panel 10, the first shielding structure 600 may be arranged in the non-display area NA of the display panel 10, and the touch control component 900 arranged in the non-display area NA and located at a side of the first shielding structure 600 away from the array base plate 100 may be shielded by the first shielding structure 600, so as not to interfere with other signals in the display panel 10. For example, the first shielding structure 600 can better shield the drive signal of the driving circuit 170 arranged in the non-display area NA, so that the touch control signal of the touch control component 900 will not interfere with the drive signal of the drive circuit 170, so as to improve the working reliability of the display panel 10.

Optionally, an orthographic projection of a portion of the touch control component 900 located in the non-display area NA on the array base plate 100 overlaps an orthographic projection of the first shielding structure 600 on the array base plate 100. Optionally, an orthographic projection of a portion of the drive circuit 170 located in the non-display area NA on the array base plate 100 overlaps the orthographic projection of the first shielding structure 600 on the array base plate 100. In these optional embodiments, by suitably setting the relative positional relationships between the first shielding structure 600 and the touch control component 900 and between the first shielding structure 600 and the drive circuit 170, the shielding effect of the first shielding structure 600 can be improved, so as to facilitate reduction of mutual interference between the touch control signal and the drive signal in the display panel 10 by the first shielding structure 600.

Optionally, the isolation structure 500 and the first shielding structure 600 are arranged in a same layer, and each of the isolation structure 500 and the first shielding structure 600 includes a one-piece structure, so that the first shielding structure 600 and the isolation structure 500 can be manufactured simultaneously in a same process step, so as to simplify the manufacturing process of the display panel 10 and increase the manufacturing efficiency of the display panel 10.

As shown in FIG. 2, optionally, each of the isolation structure 500 and the first shielding structure 600 includes a first end portion 10a facing the array base plate 100 and a second end portion 10b away from the array base plate 100, an orthographic projection of the first end portion 10a of the isolation structure 500 on the array base plate 100 is located within an orthographic projection of the second end portion 10b of the isolation structure 500 on the array base plate 100, and an orthographic projection of the first end portion 10a of the first shielding structure 600 on the array base plate 100 is located within an orthographic projection of the second end portion 10b of the first shielding structure 600 on the array base plate 100.

Optionally, the distance between the surfaces of the isolation structure 500 toward the isolation openings 500a located at both sides of the isolation structure 500 may be progressively increased in a direction away from the array base plate 100, so that the orthographic projection of the first end portion 10a of the isolation structure 500 on the array base plate 100 is located within the orthographic projection of the second end portion 10b of the isolation structure 500 on the array base plate 100.

In these optional embodiments, the orthographic projection of the first end portion 10a of the isolation structure 500 on the array base plate 100 is located within the orthographic projection of the second end portion 10b of the isolation structure 500 on the array base plate 100, so that during vapor deposition of the light-emitting layer 700 of the display panel 10, the second end portion 10b can block at least a portion of the material for manufacturing the light-emitting layer 700, so as to separate the light-emitting layers 700 of adjacent sub-pixels and facilitate forming a plurality of light-emitting units 710 that are arranged at intervals, and thus no fine mask is required for vapor deposition of the light-emitting layer 700 of the display panel 10. Therefore, for example, no Fine Metal Mask (FMM) is required for vapor deposition of the light-emitting layer 700, thereby reducing the cost for manufacturing the display panel 10.

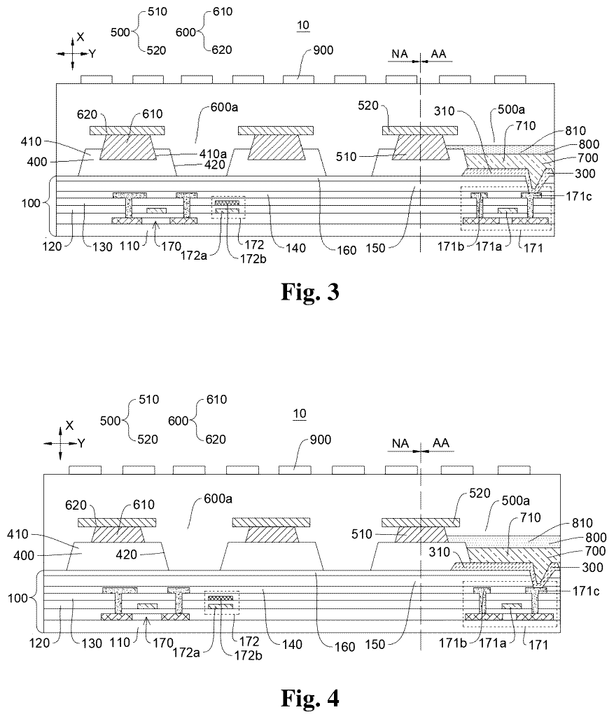

FIG. 3 shows a partial sectional view of a display panel 10 according to another embodiment of the present application, and FIG. 4 shows a partial sectional view of a display panel 10 according to yet another embodiment of the present application.

As shown in FIGS. 3 and 4, optionally, the isolation structure 500 includes a first isolation portion 510 and a second isolation portion 520 arranged at a side of the first isolation portion 510 away from the array base plate 100, and an orthographic projection of the first isolation portion 510 on the array base plate 100 is located within an orthographic projection of the second isolation portion 520 on the array base plate 100.

The isolation structure 500 includes the first isolation portion 510 and the second isolation portion 520 arranged at the side of the first isolation portion 510 away from the array base plate 100, and the orthographic projection of the first isolation portion 510 on the array base plate 100 is located within the orthographic projection of the second isolation portion 520 on the array base plate 100, so that during vapor deposition of the light-emitting layer 700 and the second electrode layer 800 of the display panel 10, the second isolation portion 520 can block at least a portion of the material for manufacturing the light-emitting layer 700 and at least a portion of the material for manufacturing the second electrode layer 800, so as to separate the light-emitting layers 700 and the second electrode layers 800 of adjacent sub-pixels and facilitate forming a plurality of light-emitting units 710 and a plurality of second electrodes 810 that are arranged at intervals, and thus no fine mask is required for vapor deposition of the light-emitting layer 700 and the second electrode layer 800. Therefore, for example, no Fine Metal Mask is required for vapor deposition of the light-emitting layer 700 and the second electrode layer 800, thereby reducing the cost for manufacturing the display panel 10.

Optionally, the display panel 10 may further include a pixel defining layer 400 arranged at a side of the array base plate 100, and the pixel defining layer 400 may include one or more pixel defining portions 410 and a plurality of pixel openings 420 defined by the pixel defining portions 410, so that the pixel defining portions 410 can be used to divide the sub-pixels of the display panel 10. Optionally, an orthographic projection of the pixel opening 420 on the array base plate 100 may be located within an orthographic projection of the isolation opening 500a on the array base plate 100.

As shown in FIG. 3, in some embodiments, the pixel defining portion 410 includes an accommodating groove 410a recessed toward the array base plate 100, and the isolation structure 500 may be arranged within the accommodating groove 410a, so that the isolation structure 500 will not have an excessively great height in comparison to the array base plate 100, so as to reduce the thickness of the display panel 10. Optionally, the first shielding structure 600 arranged in the same layer as the isolation structure 500 may also be arranged in the accommodating groove 410a of the pixel defining portion 410 located in the non-display area NA.

As shown in FIGS. 1 and 4, in some other embodiments, the isolation structure 500 may be arranged directly at a side of the pixel defining portion 410 away from the array base plate 100. Optionally, as shown in FIG. 1, the pixel opening 420 may be arranged only in the non-display area NA, or as shown in FIG. 4, the pixel opening 420 may be arranged in the display area AA and the non-display area NA.

For ease of description, in the following embodiments, for example, the isolation structure 500 is arranged at the side of the pixel defining portion 410 away from the array base plate 100. Optionally, the first shielding structure 600 arranged in the same layer as the isolation structure 500 may also be arranged at the side of the pixel defining portion 410 away from the array base plate 100.

In some optional embodiments, the display panel 10 further includes a first electrode layer 300 arranged at a side of the array base plate 100, and the first electrode layer 300 includes a plurality of first electrodes 310 arranged within the isolation openings 500a. Optionally, the first electrode 310 is located at a side of the light-emitting unit 710 facing the array base plate 100.

Optionally, the display panel 10 further includes a second electrode layer 800 arranged at a side of the array base plate 100, and the second electrode layer 800 includes a plurality of second electrodes 810 arranged within the isolation openings 500a. Optionally, the second electrode 810 is located at a side of the light-emitting unit 710 away from the array base plate 100.

Optionally, the light-emitting layer 700 is located between the first electrode layer 300 and the second electrode layer 800. Herein, the light-emitting unit 710 may include a Hole Inject Layer (HIL), a Hole Transport Layer (HTL), a light-emitting structure, an Electron Inject Layer (EIL), and an Electron Transport Layer (HTL).

Optionally, the first electrode layer 300 and the second electrode layer 800 may be pixel electrode layers, and one of the first electrode layer 300 and the second electrode layer 800 is used as an anode and the other is used as a cathode, so as to drive the light-emitting unit 710 to emit light. In the embodiments of the present application, for example, the first electrode layer 300 is the anode of the display panel 10, and the second electrode layer 800 is the cathode of the display panel 10.

Optionally, the second electrode layer 800 and the light-emitting layer 700 may be arranged only in the display area AA of the display panel 10, so as to improve the path for water vapor to invade, from the non-display area NA, into the second electrode layer 800 and the light-emitting layer 700 located in the display area AA, so that water vapor will not propagate in the display panel 10 through the second electrode layer 800 and the light-emitting layer 700, and thus the working reliability of the display panel 10 can be improved.

In some embodiments of the present application, at least a portion of the isolation structure 500 and at least a portion of the first shielding structure 600 may include an electrically conductive material, so that the second electrodes 810 within the adjacent isolation openings 500a can be electrically connected through the isolation structure 500, and further the blocking and shielding effect of the first shielding structure 600 on the touch control signals and the drive signals in the display panel 10 can be enhanced.

Optionally, the first isolation portion 510 may include an electrically conductive material, and the second electrodes 810 within the adjacent isolation openings 500a may be interconnected through the first isolation portion 510 to form a surface electrode, so as to facilitate the control of the second electrodes 810 in the display panel 10.

In some optional embodiments, the first shielding structure 600 includes a first shielding portion 610 and a second shielding portion 620 arranged at a side of the first shielding portion 610 away from the array base plate 100.

Optionally, the first shielding portion 610 includes an electrically conductive material. Optionally, the first shielding portion 610 and the first isolation portion 510 are arranged in a same layer and formed with a same material, and/or the second shielding portion 620 and the second isolation portion 520 are arranged in a same layer and formed with a same material.

In these optional embodiments, the first shielding structure 600 includes the first shielding portion 610 and the second shielding portion 620 that are stacked on the array base plate 100, and the first shielding portion 610 and the first isolation portion 510 are arranged in a same layer and formed with a same material, the second shielding portion 620 and the second isolation portion 520 are arranged in a same layer and formed with a same material, so that the first shielding structure 600 and the isolation structure 500 can be manufactured in a same process step, and thus not only mutual interference between the touch control signals and other signals in the display panel 10 can be reduced through the first shielding structure 600, but also the manufacturing process of the display panel 10 can be simplified, so as to increase the manufacturing efficiency of the display panel 10.

Optionally, the first shielding structure 600 located in the non-display area NA may be connected to the isolation structure 500 located in the display area AA to further facilitate manufacturing the first shielding structure 600 and the isolation structure 500 in a same process step, so as to further increase the manufacturing efficiency of the display panel 10.

In some optional embodiments, the first shielding structure 600 is connected to a direct current voltage signal end of the display panel 10, so that the first shielding structure 600 can be provided with a stable voltage by the direct current voltage signal end, thereby enhancing the blocking and shielding effect of the first shielding structure 600 on the touch control signals and the drive signals in the display panel 10, and thus the touch control signals and the drive signals in the display panel 10 will not interfere with each other.

Optionally, a signal line of the direct current voltage signal end may include at least one of a touch control ground signal line, an initialization signal line, a negative supply voltage signal line, or a positive supply voltage signal line.

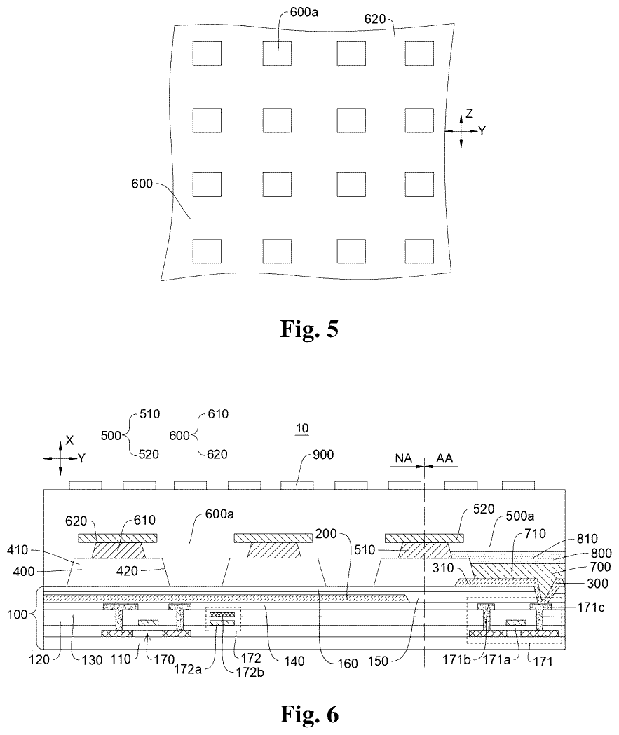

FIG. 5 shows a partial schematic structural diagram of a first shielding structure 600 according to an embodiment of the present application.

As shown in FIGS. 4 and 5, in some optional embodiments, the first shielding structure 600 includes a plurality of first shielding openings 600a which may be used to release water vapor in the display panel 10, so that the display panel 10 will not be damaged by the pressure of the water vapor. For example, the first shielding openings 600a may be used to release water vapor generated during the manufacturing process (e.g., baking) of a portion of the organic material layer structures of the display panel 10, and the first shielding openings 600a may be further used to release water vapor generated during a reliability test (simulation of a user usage scenario) of the display panel 10.

Optionally, an orthographic projection of the first shielding portion 610 on the array base plate 100 may be located within an orthographic projection of the second shielding portion 620 on the array base plate 100, so that the shape of the first shielding structure 600 may be similar to the shape of the isolation structure 500, and the first shielding opening 600a of the first shielding structure 600 may be manufactured using a similar or same manufacturing process with the isolation opening 500a, and thus the first shielding opening 600a and the isolation opening 500a can be manufactured in a same process step, which can further simplify the manufacturing process of the display panel 10 and increase the manufacturing efficiency of the display panel 10.

Optionally, the shape of the first shielding opening 600a may be set in various manners, in which the shape of the first shielding opening 600a may be set according to the requirement for releasing water vapor in the display panel 10. For example, an orthographic projection of the first shielding opening 600a on the array base plate 100 may be a polygon, a closed curve, or an irregular shape, etc., in shape.

Optionally, a plurality of first shielding openings 600a are arranged at intervals in the first direction Y and/or the second direction Z, so as to enhance the ability of the first shielding openings 600a to release water vapor.

Optionally, an orthographic projection of a portion of the touch control component 900 located in the non-display area NA on the array base plate 100 is located within an orthographic projection of the first shielding structure 600 on the array base plate 100. Optionally, an orthographic projection of the drive circuit 170 located in the non-display area NA on the array base plate 100 is located within the orthographic projection of the first shielding structure 600 on the array base plate 100. By suitably setting the size of the first shielding structure 600, the first shielding structure 600 can have a larger size to reduce mutual interference between signals, thereby improving the working reliability of the display panel 10.

FIG. 6 shows a partial sectional view of a display panel 10 according to yet another embodiment of the present application.

As shown in FIG. 6, in some optional embodiments, the display panel 10 further comprises a second shielding structure 200 located at a side of the first shielding structure 600 facing the array base plate 100, and an orthographic projection of at least a portion of the second shielding structure 200 in a thickness direction X of the display panel 10 covers the first shielding openings 600a.

Optionally, an orthographic projection of the first shielding opening 600a on the array base plate 100 is located within an orthographic projection of at least a portion of the second shielding structure 200 on the array base plate 100.

With the second shielding structure 200 located at a side of the first shielding structure 600 facing the array base plate 100, and the orthographic projection of the first shielding opening 600a on the array base plate 100 being located within the orthographic projection of at least a portion of the second shielding structure 200 on the array base plate 100, the second shielding structure 200 can better block the first shielding opening 600a in the thickness direction X of the display panel 10 to provide better blocking and shielding effect between the touch control signals and other signals in the display panel 10, so that the touch control signals and other signals in the display panel 10 will not interfere with each other through the first shielding opening 600a, thereby further improving the working reliability of the display panel 10.

Optionally, the pixel defining portions 410 further define a plurality of third shielding openings located in the non-display area NA, which may be also used to release water vapor in the display panel 10, so that the display panel 10 will not be damaged by the pressure of the water vapor.

Optionally, the third shielding openings may be spaced apart from the pixel openings 420. Optionally, an orthographic projection of the third shielding opening on the array base plate 100 may be located within an orthographic projection of the first shielding opening 600a on the array base plate 100. Optionally, an orthographic projection of at least a portion of the second shielding structure 200 in the thickness direction X of the display panel 10 covers the third shielding openings.

Optionally, the second shielding structure 200 may include an electrically conductive material. Optionally, the second shielding structure 200 is connected to a direct current voltage signal end of the display panel 10, so that the second shielding structure 200 can be provided with a stable voltage by the direct current voltage signal end, thereby enhancing the blocking and shielding effect of the second shielding structure 200 on the touch control signals and the drive signals in the display panel 10, and thus the touch control signals and the drive signals in the display panel 10 will not interfere with each other.

Optionally, a signal line of the direct current voltage signal end connected with the second shielding structure 200 may include at least one of an initialization signal line, a negative supply voltage signal line, or a positive supply voltage signal line.

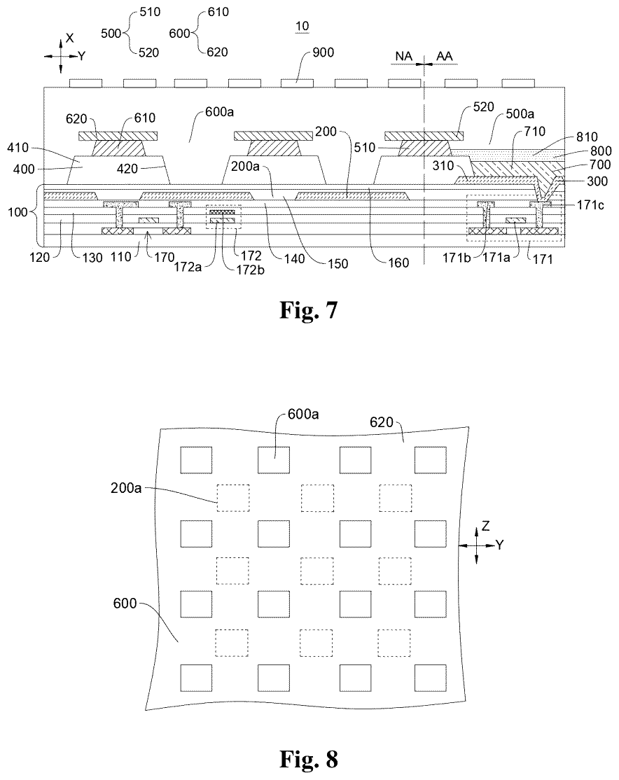

FIG. 7 shows a partial sectional view of a display panel 10 according to yet another embodiment of the present application, and FIG. 8 shows a partial schematic structural diagram of a first shielding structure 600 and a second shielding structure 200 according to an embodiment of the present application. The dashed outline in FIG. 8 is the structure outline of the second shielding opening 200a.

As shown in FIGS. 7 and 8, in some optional embodiments, the second shielding structure 200 includes a plurality of second shielding openings 200a, which may be also used to release water vapor in the display panel 10, so that the display panel 10 will not be damaged by the pressure of the water vapor. For example, the second shielding openings 200a may be used to release water vapor generated during the manufacturing process (e.g., baking) of a portion of the organic material layer structures of the display panel 10, and the second shielding openings 200a may be further used to release water vapor generated during a reliability test (simulation of a user usage scenario) of the display panel 10.

Optionally, the shape of the second shielding opening 200a may be set in various manners, in which the shape of the second shielding opening 200a may be set according to the requirement for releasing water vapor in the display panel 10. For example, an orthographic projection of the second shielding opening 200a on the array base plate 100 may be a polygon, a closed curve, or an irregular shape, etc., in shape.

In some optional embodiments, the orthographic projection of the first shielding structure 600 on the array base plate 100 is located within an orthographic projection of the second shielding structure 200 on the array base plate 100, or the orthographic projection of the first shielding structure 600 on the array base plate 100 overlaps the orthographic projection of the second shielding structure 200 on the array base plate.

By suitably setting the sizes of the second shielding structure 200 and the second shielding opening, the second shielding structure 200 can have a larger size to reduce mutual interference between signals, thereby improving the working reliability of the display panel 10.

Optionally, an orthographic projection of at least a portion of the first shielding structure 600 in the thickness direction X of the display panel 10 covers the second shielding openings 200a.

Optionally, the orthographic projection of the second shielding opening 200a on the array base plate 100 is spaced apart from the orthographic projection of the first shielding opening 600a on the array base plate 100. Optionally, the orthographic projection of the second shielding opening 200a on the array base plate 100 is located within an orthographic projection of at least a portion of the first shielding structure 600 on the array base plate 100.

In these optional embodiments, by suitably setting the relative positional relationship between the second shielding opening 200a and the first shielding opening 600a, in the thickness direction X of the display panel 10, the second shielding structure 200 can better block the first shielding opening 600a and the first shielding structure 600 can better block the second shielding opening 200a, so that the touch control signals and other signals in the display panel 10 will not interfere with each other through the first shielding opening 600a and the second shielding opening 200a, thereby further improving the working reliability of the display panel 10.

In some optional embodiments, a plurality of second shielding openings 200a are arranged at intervals in the first direction Y and/or the second direction X, so as to enhance the ability of the second shielding openings 200a to release water vapor.

In some optional embodiments, an orthographic projection of an inner wall of the second shielding opening 200a on the array base plate 100 and an orthographic projection of an inner wall of the first shielding opening 600a on the array base plate 100 is separated by a preset spacing greater than or equal to 20 micrometers.

Optionally, the preset spacing is greater than or equal to 25 micrometers and less than or equal to 35 micrometers. Optionally, the preset spacing may be 29 micrometers, 30 micrometers, or 31 micrometers.

Optionally, a plurality of first shielding openings 600a may be arranged around a portion of the second shielding openings 200a, and/or a plurality of second shielding openings 200a may be arranged around a portion of the first shielding openings 600a.

In these optional embodiments, if the preset spacing between the first shielding opening 600a and the second shielding opening 200a is too small, and for example, less than 20 micrometers, the touch control signals and other signals in the display panel 10 will interfere with each other through the first shielding opening 600a and the second shielding opening 200a that are close to each other, and thus the first shielding structure 600 and the second shielding structure 200 cannot reduce mutual interference between the touch control signals and other signals in the display panel 10; and if the preset spacing between the first shielding opening 600a and the second shielding opening 200a is too large, and for example, greater than 35 micrometers, water vapor cannot be released through the first shielding opening 600a and the second shielding opening 200a, and thus the display panel 10 will be damaged. Therefore, by suitably setting the relative positional relationship between the first shielding opening 600a and the second shielding opening 200a, the touch control signals of the display panel 10 and other signals in the display panel 10 will not interfere with each other, and moreover, the display panel 10 will not be damaged by water vapor generated in the process of manufacturing or using, thereby further improving the working reliability of the display panel 10.

In some optional embodiments, the position of the second shielding structure 200 may be set in various manners. Herein, the second shielding structure 200 may be arranged between the first shielding structure 600 and the drive circuit 170 of the array base plate 100, and an orthographic projection of at least a portion of the drive circuit 170 on the array base plate 100 is located within an orthographic projection of the second shielding structure 200 on the array base plate 100.

As shown in FIG. 7, in some optional embodiments, at least a portion of the second shielding structure 200 may be arranged within the array base plate 100. Optionally, at least a portion of the second shielding structure 200 is arranged in the same layer as at least a portion of a power signal line of the display panel 10, and/or at least a portion of the second shielding structure 200 is arranged in the same layer as at least a portion of a data signal line of the display panel 10, so that at least a portion of the second shielding structure 200 can be manufactured in the same process step as the power signal line and/or the data signal line, so as to increase the manufacturing efficiency of the display panel 10.

For example, the array base plate 100 may further include a fourth insulating layer 150 located at a side of the third insulating layer 140 away from the substrate 110, and at least a portion of the second shielding structure 200 may be arranged in the fourth insulating layer 150, and/or the array base plate 100 may further include a fifth insulating layer 160 located at a side of the fourth insulating layer 150 away from the substrate 110, and at least a portion of the second shielding structure 200 may be arranged in the fifth insulating layer 160.

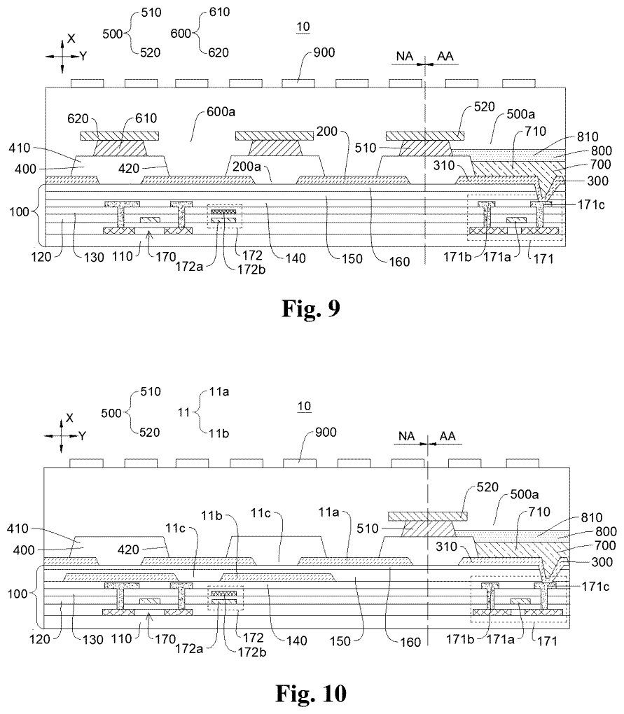

FIG. 9 shows a partial sectional view of a display panel 10 according to yet another embodiment of the present application.

As shown in FIG. 9, in some optional embodiments, at least a portion of the second shielding structure 200 may be further arranged between the array base plate 100 and the first shielding structure 600. Optionally, at least a portion of the second shielding structure 200 may be arranged in the same layer as the first electrode 310. Optionally, at least a portion of the second shielding structure 200 and the first electrode 310 may be arranged in a same layer and formed with a same material, so that at least the portion of the second shielding structure 200 and the first electrode 310 can be manufactured in a same process step, and thus not only mutual interference between the touch control signals and other signals in the display panel 10 can be reduced through the second shielding structure 200, but also the manufacturing process of the display panel 10 can be simplified, so as to increase the manufacturing efficiency of the display panel 10.

FIG. 10 shows a partial sectional view of a display panel according to yet another embodiment of the present application.

As shown in FIG. 10, the embodiments of the first aspect of the present application further provide a display panel 10 with a display area AA and a non-display area NA, the display panel 10 includes: an array base plate 100; a light-emitting layer 700 arranged on the array base plate 100 and including a plurality of light-emitting units 710; a shielding layer 11 located in the non-display area NA and arranged at a side of the light-emitting layer 700 facing the array base plate 100, the shielding layer 11 including a first shielding layer 11a and a second shielding layer 11b located at a side of the first shielding layer 11a away from the light-emitting layer 700; and a touch control component 900 at least partially located at a side of the shielding layer 11 away from the array base plate 100.

In the embodiment, the structures of the array base plate 100 and the light-emitting layer 700 may be the same or similar with the structures of the array base plate 100 and the light-emitting layer 700 as described in any of the above embodiments, respectively. With the first shielding layer 11a and the second shielding layer 11b that are stacked in the non-display area AA of the display panel 10, mutual interference between the signal in the array base plate 100 and the touch control signal in the touch control component 900 can be reduced, so as to improve the working reliability of the display panel 10.

Optionally, the display panel 10 further includes a first electrode layer 300 arranged at a side of the array base plate 100, and the first electrode layer 300 includes a plurality of first electrodes 310 arranged between the light-emitting units 710 and the array base plate 100.

Optionally, the display panel 10 may further include an isolation structure 500 arranged in the display area AA. During vapor deposition of the light-emitting layer 700 of the display panel 10, the isolation structure 500 can block at least a portion of the material for manufacturing the light-emitting layer 700, so as to separate the light-emitting layers 700 of adjacent sub-pixels and facilitate forming a plurality of light-emitting units 710 that are arranged at intervals.

Optionally, the display panel 10 further includes a second electrode layer 800 arranged at a side of the array base plate 100, and the second electrode layer 800 includes a plurality of second electrodes 810 arranged within the isolation openings 500a. Optionally, the second electrode 810 is located at a side of the light-emitting unit 710 away from the array base plate 100.

In some embodiments of the present application, the position of the shielding layer 11 may be set in various manners. Herein, the shielding layer 11 is arranged between the touch control component 900 and a driving circuit 170 of the array base plate 100, and an orthographic projection of at least a portion of the drive circuit 170 on the array base plate 100 is located within an orthographic projection of the shielding layer 11 on the array base plate 100.

In some optional embodiments, at least a portion of the shielding layer 11 is arranged in the same layer as the first electrode 310, and/or at least a portion of the shielding layer 11 is arranged in the same layer as at least a portion of a power signal line of the display panel 10, and/or at least a portion of the shielding layer 11 is arranged in the same layer as at least a portion of a data signal line of the display panel 10, so that at least a portion of the shielding layer 11 can be manufactured in the same process step as the first electrode 310, the power signal line, and/or the data signal line, so as to increase the manufacturing efficiency of the display panel 10.

Optionally, the first shielding layer 11a may be arranged between the light-emitting layer 700 and the fifth insulating layer 160 and/or on the fifth insulating layer 160 of the array base plate 100, and the second shielding layer 11b may be arranged in any layer between the first shielding layer 11a and the third insulating layer 140.

For example, the first shielding layer 11a may be arranged between the light-emitting layer 700 and the fifth insulating layer 160 and in the same layer as the first electrode 310, and the second shielding layer 11b may be arranged in the fourth insulating layer 150.

In some optional embodiments, the shielding layer 11 includes one or more air holes 11c, which may be used to release water vapor in the display panel 10, so that the display panel 10 will not be damaged by the pressure of the water vapor.

Optionally, each of the first shielding layer 11a and the second shielding layer 11b includes the air hole 11c, wherein an orthographic projection of at least a portion of the first shielding layer 11a in a thickness direction X of the display panel 10 covers the air hole 11c in the second shielding layer 11b, and/or an orthographic projection of at least a portion of the second shielding layer 11b in the thickness direction X of the display panel 10 covers the air hole 11c in the first shielding layer 11a.

Optionally, an orthographic projection of the air hole 11c in the first shielding layer 11a on the array base plate 100 is spaced apart from an orthographic projection of the air hole 11c in the second shielding layer 11b on the array base plate 100.

In these optional embodiments, by suitably setting the relative positional relationship between the air hole 11c in the first shielding layer 11a and the air hole 11c in the second shielding layer 11b, in the thickness direction X of the display panel 10, the first shielding layer 11a can better block the air hole 11c in the second shielding layer 11b, and the second shielding layer 11b can better block the air hole 11c in the first shielding layer 11a, so that the touch control signals and other signals in the display panel 10 will not interfere with each other through the air holes 11c, thereby further improving the working reliability of the display panel 10.

The embodiments of the second aspect of the present application provide a display apparatus including the display panel 10 according to any of the above embodiments. Since the display apparatus according to the embodiments of the second aspect of the present application includes the display panel 10 according to any of the above embodiments of the first aspect, the display apparatus has the beneficial effect of the display panel 10, which will not be repeated herein.

The display apparatus in the embodiments of the present application includes, but is not limited to, a cellular phone, a Personal Digital Assistant (PDA), a tablet computer, an e-book, a television, an entrance guard, a smart fixed-line phone, a console, and other apparatus with display function.

The above embodiments of the present application do not exhaustively describe all the details, nor do they limit the present application to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims and the full scope and equivalents of the claims.

What is claimed is:

1. A display panel with a display area and a non-display area, the display panel comprising:
an array base plate;
a light-emitting layer arranged on the array base plate and comprising a plurality of light-emitting units;
an isolation structure located in the display area, the isolation structure being arranged on the array base plate and comprising a plurality of isolation openings, the light-emitting units being located within the isolation openings;
a first shielding structure located in the non-display area and arranged in the same layer as at least a portion of the isolation structure; and
a touch control component at least partially located at a side of the first shielding structure away from the array base plate.

2. The display panel according to claim 1, wherein each of at least a portion of the isolation structure and at least a portion of the first shielding structure comprises an electrically conductive material; and the isolation structure and the first shielding structure are arranged in a same layer, and each of the isolation structure and the first shielding structure comprises a one-piece structure.

3. The display panel according to claim 2, wherein each of the isolation structure and the first shielding structure comprises a first end portion facing the array base plate and a second end portion away from the array base plate, an orthographic projection of the first end portion of the isolation structure on the array base plate is located within an orthographic projection of the second end portion of the isolation structure on the array base plate, and an orthographic projection of the first end portion of the first shielding structure on the array base plate is located within an orthographic projection of the second end portion of the first shielding structure on the array base plate; and
each of the first end portion of the isolation structure and the first end portion of the first shielding structure comprises the electrically conductive material.

4. The display panel according to claim 2, wherein the isolation structure comprises a first isolation portion and a second isolation portion arranged at a side of the first isolation portion away from the array base plate, an orthographic projection of the first isolation portion on the array base plate is located within an orthographic projection of the second isolation portion on the array base plate, the first shielding structure comprises a first shielding portion and a second shielding portion arranged at a side of the first shielding portion away from the array base plate, and an orthographic projection of the first shielding portion on the array base plate is located within an orthographic projection of the second shielding portion on the array base plate;
the first shielding portion and the first isolation portion are arranged in a same layer and formed with a same material, or the second shielding portion and the second isolation portion are arranged in a same layer and formed with a same material; and
the first shielding portion and the first isolation portion comprise the electrically conductive material.

5. The display panel according to claim 1, wherein the first shielding structure is connected to a direct current voltage signal end of the display panel; and
a signal line of the direct current voltage signal end comprises at least one of a touch control ground signal line, an initialization signal line, a negative supply voltage signal line, or a positive supply voltage signal line.

6. The display panel according to claim 1, wherein the first shielding structure comprises a plurality of first shielding openings;
a plurality of the first shielding openings are arranged at intervals in a first direction or a second direction, wherein the first direction is intersected with the second direction;
an orthographic projection of a portion of the touch control component located in the non-display area on the array base plate is located within an orthographic projection of the first shielding structure on the array base plate; and
the array base plate further comprises a drive circuit, and an orthographic projection of the drive circuit located in the non-display area on the array base plate is located within the orthographic projection of the first shielding structure on the array base plate.

7. The display panel according to claim 6, wherein the display panel further comprises a second shielding structure located at a side of the first shielding structure facing the array base plate, an orthographic projection of at least a portion of the second shielding structure in a thickness direction of the display panel covers the first shielding openings.

8. The display panel according to claim 7, wherein the display panel further comprises a pixel defining layer arranged at a side of the array base plate, the pixel defining layer comprises one or more pixel defining portions and a plurality of pixel openings defined by the pixel defining portions; and
the pixel defining portions further define a plurality of third shielding openings located in the non-display area, an orthographic projection of at least a portion of the second shielding structure in the thickness direction of the display panel covers the third shielding openings.

9. The display panel according to claim 7, wherein the second shielding structure comprises an electrically conductive material;
the second shielding structure is connected to a direct current voltage signal end of the display panel;
a signal line of the direct current voltage signal end comprises at least one of an initialization signal line, a negative supply voltage signal line, or a positive supply voltage signal line;
the second shielding structure comprises a plurality of second shielding openings, an orthographic projection of at least a portion of the first shielding structure in the thickness direction of the display panel covers the second shielding openings;
a plurality of the second shielding openings are arranged at intervals in the first direction or the second direction;
the orthographic projection of the first shielding structure on the array base plate is located within an orthographic projection of the second shielding structure on the array base plate, or the orthographic projection of the first shielding structure on the array base plate overlaps the orthographic projection of the second shielding structure on the array base plate; and
an orthographic projection of an inner wall of the second shielding opening on the array base plate and an orthographic projection of an inner wall of the first shielding opening on the array base plate is separated by a preset spacing greater than or equal to 20 micrometers.

10. The display panel according to claim 9, wherein the preset spacing is greater than or equal to 25 micrometers and less than or equal to 35 micrometers.

11. The display panel according to claim 7, wherein the second shielding structure is arranged between the first shielding structure and the drive circuit of the array base plate, an orthographic projection of at least a portion of the drive circuit on the array base plate is located within an orthographic projection of the second shielding structure on the array base plate.

12. The display panel according to claim 11, wherein the display panel further comprises a first electrode layer arranged at a side of the array base plate, and the first electrode layer comprises a plurality of first electrodes arranged within the isolation openings.

13. The display panel according to claim 12, wherein at least a portion of the second shielding structure is arranged in the same layer as the first electrode, or at least a portion of the second shielding structure is arranged in the same layer as at least a portion of a power signal line of the display panel, or at least a portion of the second shielding structure is arranged in the same layer as at least a portion of a data signal line of the display panel.

14. The display panel according to claim 12, wherein at least a portion of the second shielding structure is arranged in the same layer as at least a portion of a power signal line of the display panel, or at least a portion of the second shielding structure is arranged in the same layer as at least a portion of a data signal line of the display panel; and
the second shielding structure and the first electrode are arranged in a same layer and formed with a same material.

15. The display panel according to claim 1, wherein the display panel further comprises a second electrode layer arranged in the display area, and the second electrode layer comprises a plurality of second electrodes arranged within the isolation openings, and the second electrode being located at a side of the light-emitting unit away from the array base plate.

16. A display apparatus comprising the display panel according to claim 1.

17. A display panel with a display area and a non-display area, the display panel comprising:
an array base plate;
a light-emitting layer arranged on the array base plate and comprising a plurality of light-emitting units;
a shielding layer located in the non-display area and arranged at a side of the light-emitting layer facing the array base plate, the shielding layer comprising a first shielding layer and a second shielding layer located at a side of the first shielding layer away from the light-emitting layer; and
a touch control component at least partially located at a side of the shielding layer away from the array base plate.

18. The display panel according to claim 17, wherein the shielding layer is arranged between the touch control component and a driving circuit of the array base plate, an orthographic projection of at least a portion of the drive circuit on the array base plate is located within an orthographic projection of the shielding layer on the array base plate.

19. The display panel according to claim 18, wherein the display panel further comprises a first electrode layer arranged at a side of the array base plate, and first electrode layer comprises a plurality of first electrodes arranged between the light-emitting units and the array base plate; and
at least a portion of the shielding layer is arranged in the same layer as the first electrode, or at least a portion of the shielding layer is arranged in the same layer as at least a portion of a power signal line of the display panel, or at least a portion of the shielding layer is arranged in the same layer as at least a portion of a data signal line of the display panel.

20. The display panel according to claim 17, wherein the shielding layer comprises one or more air holes; and
each of the first shielding layer and the second shielding layer comprises the air hole, wherein an orthographic projection of at least a portion of the first shielding layer in a thickness direction of the display panel covers the air hole in the second shielding layer, or an orthographic projection of at least a portion of the second shielding layer in the thickness direction of the display panel covers the air hole in the first shielding layer.
